(19) United States
(12) Patent Application Publication
(10) Pub. No.: US 2005/0094465 A1
(43) Pub. Date: May 5, 2005

(54) Printed circuit board memory module with embedded passive components

(75) Inventors: William M. Gervasi, Ladera Ranch, CA (US); Jayesh R. Bhakta, Cerritos, CA (US); Robert S. Pauley, Mission Viejo, CA (US)

Correspondence Address: KLEIN, O'NEILL & SINGH, 2 PARK PLAZA, SUITE 510, IRVINE, CA, 92614, US

(73) Assignee: NETLIST INC., Irvine, CA (US)

(21) Appl. No.: 10/979,305

(22) Filed: Nov. 2, 2004

Related U.S. Application Data
(60) Provisional application No. 60/516,684, filed on Nov. 3, 2003.
(60) Provisional application No. 60/553,113, filed on Mar. 15, 2004.

(51) Int. Cl. H01L 23/34

(52) U.S. Cl. 365/222

(57) ABSTRACT

A memory module includes a plurality of memory components mounted on a printed circuit board, and a plurality of passive components embedded within the board directly underneath the memory components to minimize the space occupied by the passive components and the lengths of the required conductive traces. The passive components and the memory components are connected by conductor-filled vias between the contacts of the embedded components and the memory components mounted above them on the board surface. The passive components may be thick film resistors, either series damping resistors or differential damping resistors. By embedding the resistors directly beneath the memory components, there is enough space on the board to provide a set of termination resistors for each of the several memory components on the board, thereby eliminating the need for a single resistor to be shared by two or more memory components, resulting in more precise output signals.

### CROSS-REFERENCE TO RELATED APPLICATIONS

This application claims the benefit, under 35 U.S.C. § 119(e), of co-pending provisional application No. 60/516,684; filed Nov. 3, 2003, and of co-pending provisional application No. 60/553,113; filed Mar. 15, 2004, the disclosures of which are incorporated herein by reference.

### FEDERALLY SPONSORED RESEARCH OR DEVELOPMENT

Not Applicable

### BACKGROUND OF THE INVENTION

The present invention relates broadly to the field of printed circuits, and more particularly to a printed circuit boards on which are mounted solid state memory components. More specifically, the present invention relates to a “very low profile” (VLP) memory module, comprising a plurality of solid state memory components on a circuit board that also includes discrete surface mount (“SMT”) passive components, or thick film resistors that are embedded within the circuit board material.

Modern computer systems typically employ one or more memory modules, each comprising a plurality of dynamic random access memory (DRAM) components mounted in a horizontal row on a printed circuit (PC) board. A typical arrangement, for example, comprises a plurality of DRAM components arranged linearly on a PC board, with conductive traces leading from the terminals of the DRAM components to connector contacts on the edge of board. In small form factor applications, such as blade servers, the connector contacts are typically angled with respect the major board surface, so as to allow the memory module PC boards to be mounted in mating sockets on a “motherboard” at an offset angle relative to the vertical to reduce their effective vertical height.

To maintain good signal integrity, passive components, such as resistors, capacitors, and inductors, have been mounted on the surface of the board at locations selected to provide series damping termination or differential termination. Typically, the passive components are located between the DRAM components and the connector contacts.

The use of surface-mount components requires the dedication of precious PC board surface area to accommodate their “footprints.” With a need for increased component densities and higher speeds of operation, “Very Low Profile” (VLP) memory modules have been developed that have a vertical height of about 18.3 mm. This VLP configuration allows the modules to be mounted vertically on the motherboard, thereby reducing the space needed between adjacent module boards, as well as reducing the overall space required for the modules. Furthermore, the reduced height of the VLP modules allows for a reduction in the length of the conductive traces between the DRAM components and the connector contacts, thereby allowing for increased operational speeds. The reduced surface area of the VLP modules presents a challenge, however, for the placement of surface mount (“SMT”) passive components. While some reduction in the “footprint” of SMT components can be achieved, there are limits in the degree of size reduction that can be achieved economically. Furthermore, small form factor SMT resistors are inherently more difficult to handle than those with larger footprints during manufacture and assembly.

One possible approach to solving the PC board space problem for passive components may be suggested by the use of “embedded” passive components, in which the passive components are located below the surface of the PC board, “embedded,” so to speak, within the board material itself. This allows the embedded components to be located directly underneath surface-mounted components, thereby allowing much more efficient use of the space on the PC board surface, with increased component densities. While this approach has been used in such devices as mobile (“cell”) telephones and other miniature electronic devices, heretofore, this technology has not been used in conjunction with computer memory modules. Furthermore, the VLP module technology has not been developed to take full advantage of the embedded passive components both to maximize performance and to minimize space requirements.

### SUMMARY OF THE INVENTION

Broadly, the present invention is a VLP memory module, comprising a plurality of memory components (e.g., DRAMs) mounted on a printed circuit (PC) board, and a plurality of passive components embedded within the PC board in locations that minimize the PC board surface area occupied by the passive components, while also minimizing the lengths of the conductive paths between the memory components and the passive components. In a specific preferred embodiment, the passive components are located directly underneath the memory components, and the conductive paths between the passive components and the memory components are provided by conductive vias between the terminals of the embedded components and the memory components mounted above them on the surface of the board. The passive components in the specific preferred embodiment are thick film resistors, either series damping resistors or differential damping resistors. By embedding the resistors directly beneath the memory components, there is enough space on the board to provide a set of termination resistors for each of the several memory components on the board, thereby eliminating the need for a single resistor to be shared by two or more memory components. The result is much “cleaner” and precise output signals; that is, the output signals are less noisy and suffer less variance from their nominal values.

Another aspect of the invention is that by embedding the passive components underneath the memory components, the passive components can be made larger than if they were to have their own dedicated board surface area. With resistors, in particular, their larger physical size (i.e., surface area) offers the advantage that absolute deviations from their nominal dimensions will result in much smaller deviations from their nominal resistance values. Specifically, the embedded thick film resistors are made with resistive inks that have fixed sheet resistance values. The resistive ink is printed between a pair of spaced-apart contact pads, thereby providing a resistor with a defined surface area and thus a defined resistance, the surface area and thus the resistance being within known and manageable tolerances. Typical embedded resistors may have tolerances of, for example, ±15% in their physical dimensions. Such wide tolerances may result in performance-affecting variances from their nominal resistances when the surface area of the resistor is relatively small. By substantially increasing the surface area of the resistor, however, the effect on the resistance value of such variations in the physical dimensions is proportionately reduced.

As will be further appreciated from the detailed description that follows, the advantages discussed above, as well as others that will be appreciated by those skilled in the pertinent arts, are provided in a PC board module that can be easily and economically manufactured with known circuit board manufacturing equipment and techniques.

### BRIEF DESCRIPTION OF THE DRAWINGS

FIGS. 1 and 2 are semi-diagrammatic side elevational views of a first or lower layer of PC board material, showing the first two major steps in the process of manufacturing a printed circuit (PC) board memory module in accordance with the present invention;

FIG. 3 is a semi-diagrammatic top plan view of a portion of a first or lower layer of PC board material, after the deposition of a thick film resistor;

FIG. 4 is a semi-diagrammatic cross-sectional view taken along line 4-4 of FIG. 3, but after completion of the step of laminating a second layer of PC board material on top of the first layer;

FIGS. 5-7 are semi-diagrammatic cross-sectional views, similar to that of FIG. 4, showing the subsequent steps in the process of manufacturing a PC board memory module in accordance with the present invention;

FIG. 8 is a semi-diagrammatic cross-sectional view of a conventional, prior art PC board memory module;

FIG. 9 is a top plan view of a PC board used in conventional, prior art PC board memory module, before the installation of the memory components;

FIG. 10 is a top plan view of the PC board of the present invention, before the installation of the memory components;

FIG. 11 is a graphic view of an exemplary output clock signal achievable in the prior art;

FIG. 12 is a graphic view of an exemplary output clock signal achievable with the present invention;

FIG. 13 is a semi-diagrammatic view of a portion of a PC board memory module in accordance with the present invention, showing a first arrangement of differential termination resistors; and

FIG. 14 is a semi-diagrammatic view of a portion of a PC board memory module in accordance with the present invention, showing a second arrangement of differential termination resistors.

### DETAILED DESCRIPTION OF THE INVENTION

Referring first to FIG. 8, a typical, prior art PC board memory module 10 is shown. The module 10 comprises a printed circuit board 12 on which is mounted a plurality of solid state memory components 14, such as DRAMs, only one of which is shown. The DRAM 14 typically has short terminal contacts 16, which may be of the type known as a “ball grid array.” The DRAM terminal contacts 16, in turn, are soldered to conductive contact pads 18 formed on the surface of the board 12 by conventional means, well-known in the art. One edge of the board 12 is provided with a plurality of connector contacts 20, which allow the board 12 to be plugged into a mating socket (not shown) on a larger board or “motherboard” (not shown).

Passive components, such as a termination resistor 22, are mounted on the surface of the board 12 between the DRAM 14 and the connector contacts 20. The termination resistor 22 is a typical “surface mount technology” (SMT) component, which is soldered to conductive contact pads 24 located on the surface of the board 12, after the installation of the DRAM 14. The resistor 22 is electrically connected to the appropriate memory component terminal contact 16 by means of a conductive trace 26 that connects one of the resistor contact pads 24 to the appropriate contact pad 18 for the memory component or DRAM 14. The conductive trace may be made of any suitable metal, copper being preferred. At least a portion of the conductive trace 26 may be embedded within the PC board 12, as shown in the drawing. This is done by forming the board from a first or lower layer of board material (typically FR4), and then depositing the embedded portion of the trace 26 on the exposed surface of the lower board layer by conventional means. A second or upper layer of board material is formed (e.g., by lamination) on top of the first layer, and vias 28 are drilled through the upper layer and are filled with the conductive metal (e.g., copper) that forms the trace 26. Although only one resistor 22 is shown, it will be appreciated that a plurality of resistors (or other passive SMT components) will be mounted on the board, each with appropriate conductive traces connecting it to at least one DRAM, and frequently more than one.

It will be appreciated that the prior art module 10 described above and shown in FIG. 8 requires a significant amount of board surface area to be occupied by the discrete SMT resistor 22. This puts a premium on minimizing the surface area of each resistor, with deleterious effects on the resistance tolerances, as discussed above. Furthermore, the lengths of the conductive traces needed to connect the passive components to the DRAMs limits the operational speed of the module. Finally, because of space limitations, the number of SMT resistors 22 is minimized, requiring each such resistor 22 to be connected as a termination resistor to two or more DRAMs, thereby degrading signal quality.

The present invention addresses the above-discussed addresses the limitations of the prior art by embedding the passive components within the circuit board, directly underneath the surface-mounted memory components.

Referring first to FIG. 1, a first or lower layer 30 of PC board material is provided, on the surface of which a pattern of conductive metal, preferably copper, is deposited by conventional means, e.g., by electro-deposition or lamination of a copper layer, then masking, and selective etching. The metal pattern forms a plurality of first contact pads 32 and a plurality of second contact pads 34, with a horizontal trace 36 extending toward one board edge from each of the second contact pads 34. (For simplicity, only a single arrangement of first and second contact pads 32, 34 and trace 36 is shown, it being understood that a plurality of such arrangements will normally be provided, one for each embedded passive component).

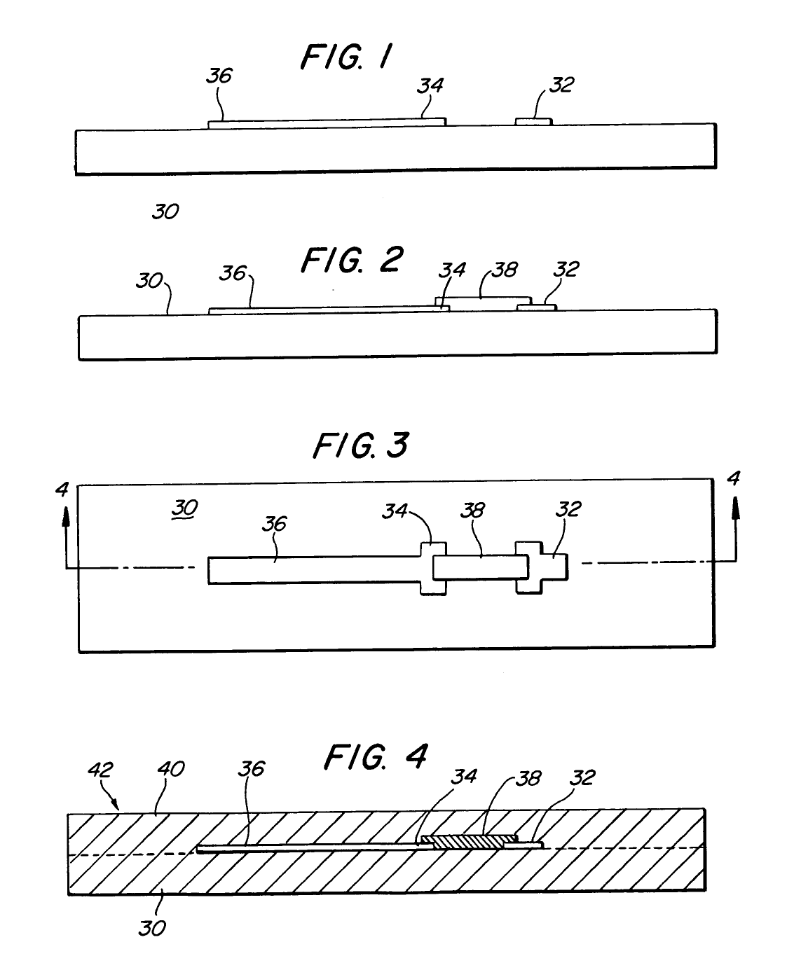

FIGS. 2 and 3 illustrate the formation of a plurality of passive components, as exemplified by a resistor 38, on the first board layer 30. Each of the resistors 38 is a thick film resistor formed by conventional screen printing or equivalent techniques, so as to bridge one of the first contact pads 32 and one of the second contact pads 34. As shown in FIG. 4, a second or upper layer 40 of PC board material is applied (e.g., by lamination) on top of the first layer 30, thereby forming a PC board 42, in which the resistors 38, the first contact pads 32, the second contact pads 34, and the horizontal traces 36 are embedded. The first contact pads, the second contact pads 34, and the horizontal traces 36 will now be referred to as the “embedded” contact pads 32, 34 and the “embedded” traces 36.

FIG. 5 illustrates an array of memory component contact pads 44 formed, by conventional techniques (as described above) on the upper surface of the PC board 42. At the same time, an array of edge connector contacts 46 is formed on at least one of the major surfaces of the PC board 42, near one of its longer edges (assuming the board is rectangular).

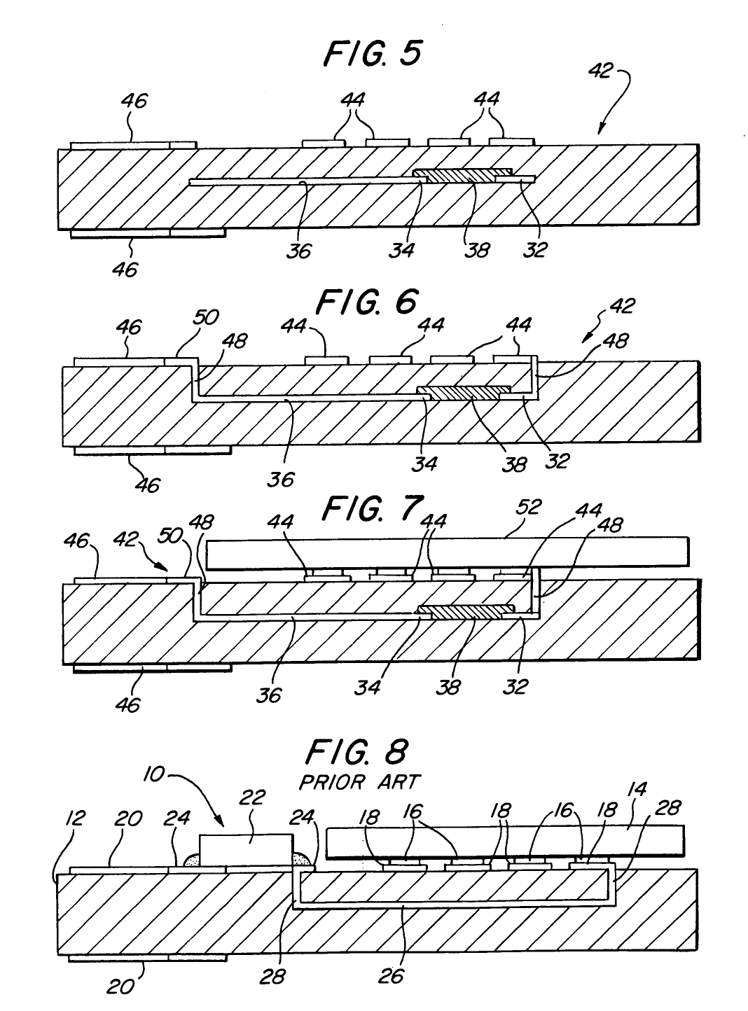

FIG. 6 illustrates the board 42 after vias 48 are formed (e.g., by laser or mechanical drilling) in the upper surface thereof. The vias 48 extend down to the free end (the end closest to the edge connector contact array) of the embedded trace 36 and to the first embedded contact pad 32. The vias 48 are then filled with conductive metal (e.g., copper) so that each of the first embedded contact pads 32 is electrically connected to an appropriate one of the memory component contact pads 44, and each of the embedded traces 36 is connected to an appropriate one of the connector contacts 46. It may be necessary to provide a short surface trace 50 to establish a conductive path between each embedded trace 36 and its respective edge connector contact 46.

Finally, as shown in FIG. 7, each of a plurality of solid state memory components (e.g., DRAMs 52, only one of which is shown) is soldered onto its respective array of surface contact pads 44. Thus it can be seen that the embedded resistor 38 is located directly underneath the DRAM 52, and nor surface are of the PC board 42 needs to be dedicated to the resistor 38.

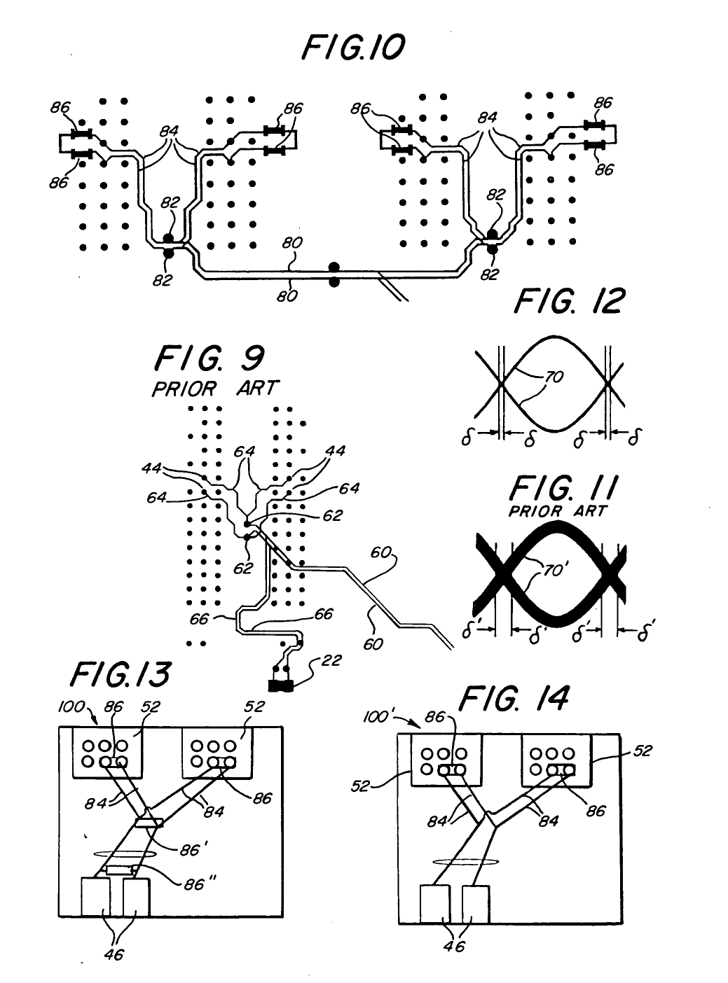

FIGS. 9 and 10 illustrate the contrasting topographies or lay-outs of a prior art PC board memory module (FIG. 9) and that of the present invention (FIG. 10). (For clarity, the respective memory modules are shown before the memory components are installed.) In the prior art, shown in FIG. 9, a pair of clock signal input traces 60 is formed on the surface of the board, leading to a pair of branch point contacts 62. Leading from each branch point contact 62, in turn, is an unterminated differential pair of DRAM traces 64, each of which connects to an appropriate DRAM surface contact 44. Each of the unterminated DRAM traces connects to a separate DRAM (not shown). As discussed above in connection with the prior art device shown in FIG. 8, to provide the needed termination resistance, a discrete SMT termination resistor 22 is mounted on the board near the connector edge thereof. This requires a pair of termination traces 66 extending from the branch point contacts 64 to the respective contacts (not shown) of the SMT termination resistor 22.

The prior art board topography shown in FIG. 9 not only requires additional board space to accommodate the SMT resistor 22 and its termination traces 66, but the length of the traces degrades signal quality, as does the need to have each SMT resistor terminate two or more DRAMs. This latter point is graphically illustrated in FIG. 11, in which an exemplary output clock signal 70 from a typical prior art memory module is shown. It can be seen that the clock signal crossing uncertainty or deviation 6 from the nominal signal value caused by signal reflections, is quite large.

The board topography of the present invention, as shown in FIG. 10, provides a more compact and efficient lay-out. Specifically, for each adjacent pair of memory components or DRAMs (not shown), a pair of clock signal input traces 80 leads to a pair of branch point contacts 82. First and second differential signal pairs of embedded terminated branch traces 84 extend from the pair of branch point contacts 82 respectively to the areas underneath each of the adjacent pair of DRAMs (not shown), where each pair of differential branch traces 84 is terminated by a series pair of embedded termination resistors 86. While a series pair of termination resistors 86 is preferred for the sake of improved tolerances, a single termination resistor, of twice the resistance of each of the series pair 86, can be used.

The arrangement shown in FIG. 10 not only avoids the need to dedicate precious board space to the termination resistors, but it also reduces the overall length of the conductive traces needed for each terminated differential pair of traces. Furthermore, each DRAM can have its own terminated differential pair, rather than having two DRAMs share a single terminated pair, as shown in the prior art arrangement of FIG. 9. Another advantage of the arrangement of FIG. 10 is that each of the termination resistors 86 can be physically larger than has heretofore been practical in the prior art. As explained above, this allows greater precision in the achievable resistance. The result is a “cleaner” output clock signal, as shown in FIG. 12, in which an exemplary output clock signal 70′ is shown with a deviation 6′ from the nominal signal value that is much smaller than the deviation achievable in the prior art (FIG. 11).

FIGS. 13 and 14 show two possible arrangements of differential termination resistors in accordance with the present invention. FIG. 13, for example, illustrates, semi-diagrammatically, a portion of an exemplary PC board memory module 100 having an adjacent pair of memory components (e.g., DRAMs 52), each of which is connected to a pair of edge connector contacts 46 by a differential pair of traces 84. The end of each differential trace pair 84 is terminated by an embedded resistor 86, located directly beneath its respective DRAM 52. If desired for further reduction of signal noise from the signal branches or from connector interference, the differential trace pairs 84 may be terminated at other critical points by additional embedded resistors 86′ and 86″, as shown in FIG. 13. Ideally, however, a module 100′ with the arrangement shown in FIG. 14 can be employed, using only the termination resistors 86 embedded underneath the DRAMs 52 to terminate only the end of each differential trace pair 84. With either of these arrangements, it may be possible to eliminate the need for false termination branches from the differential termination pair (as shown, for example, in FIG. 9), and improved signal quality (as discussed above in connection with FIGS. 11 and 12) can be achieved.

It will be understood to those skilled in the pertinent arts that other types of passive components, such as capacitors and inductors, can be embedded in the PC board in suitable locations for signal treatment in accordance with any number of appropriate applications. The techniques for creating these embedded capacitors and inductors are known in the art, and therefore the scope of the present invention is not limited to the embedded resistors discussed above and shown in the drawings. Indeed, a number of variations and modifications of the invention will suggest themselves to those skilled in the pertinent arts, as well as equivalents to the structures, components, and methods herein. Therefore, all such variations, modifications, and equivalents should be considered within the spirit and scope of the present invention, as defined in the claims that follow.

1. A printed circuit board memory module, comprising:
a printed circuit board having a major surface and an edge;
a plurality of memory components mounted on the major surface of the board;
a plurality of connector contacts arranged along the edge of the board;
a plurality of passive components, each of which is embedded within the circuit board beneath one of the memory components; and
a conductive trace connecting each of the passive components to at least one of the connector contacts.

2. The printed circuit board memory module of claim 1, wherein at least some of the passive components are thick film resistors.

3. The printed circuit board memory module of claim 1, wherein a substantial portion of each of the conductive traces is embedded within the circuit board.

4. The printed circuit board memory module of claim 2, wherein the conductive traces are first conductive traces, wherein the memory module further comprises a plurality of second conductive traces, each of which forms a differential trace pair with one of the first conductive traces, and wherein each of the resistors terminates one of the differential trace pairs.

5. A printed circuit board memory module, comprising:
a printed circuit board having a major surface and an edge;
a plurality of memory components mounted on the major surface of the board;
a plurality of connector contacts arranged along the edge of the board;
a pair of conductive traces connecting each of the memory components to selected ones of the connector contacts; and
a plurality of thick film resistors, each embedded within the board beneath one of the memory components, each terminating the pair of conductive traces connecting the memory component to the connector contacts.

6. The printed circuit board memory module of claim 5, wherein at least a portion of each of the conductive traces is embedded within the board.

7. The printed circuit board memory module of claim 5, wherein the pair of traces is a differential signal trace pair.

8. The printed circuit board memory module of claim 6, wherein each of the conductive traces is connected to a connector contact by a conductor-filled via.

9. The printed circuit board memory module of claim 8, wherein the conductor-filled via is a first conductor-filled via, and wherein each of the resistors bridges first and second embedded contact pads, the first contact pad being connected to the memory component by a second conductor-filled via, and the second contact pad being connected to one of the conductive traces.

10. A method of making a printed circuit board memory module, comprising:
providing a first layer of circuit board material having a major surface and an edge;
forming a pattern of a plurality of first contact pads, a plurality of second contact pads, and a plurality of conductive traces, each extending from one of the second contact pads toward the edge;
forming a plurality of passive components, each of which bridges one of the first contact pads and one of the second contact pads;
applying a second layer of circuit board material over the first layer so as to form a circuit board in which the passive components, the first and second contact pads, and the traces are embedded, the board having a major surface and an edge;
forming a pattern of metallized memory component contact pads and a pattern of metallized connector contacts on the major surface of the board;
forming a first plurality of conductor-filled vias, each connecting one of the first contact pads with a selected one of the memory component contact pads;
forming a second plurality of conductor-filled vias, each connecting one of the second contact pads with one of the connector contacts; and
installing a memory component on the memory component contact pads.

11. The method of claim 10, wherein the pattern of connector contacts is formed adjacent the edge of the board.

12. The method of claim 10, wherein at least some of the passive components are resistors.

13. The method of claim 12, wherein the resistors are thick film resistors.

14. The method of claim 10, wherein the pattern of memory component contact pads is formed at a location on the major surface of the board that directly overlies at least one of the passive components.

15. A printed circuit board memory module, comprising:
a printed circuit board having a major surface and an edge;
a plurality of memory components mounted on the major surface;
at least one thick film resistor embedded within the printed circuit board directly beneath each of the memory components;
a plurality of connector contacts arranged along the edge of the board; and
a plurality of conductive traces embedded below the major surface of the board, each connecting one of the resistors with one of the connector contacts.

16. The printed circuit board memory module of claim 15, wherein the plurality of conductive traces includes a pair of differential signal traces for each of the memory components, and where each of the resistors terminates a pair of differential signal traces.

17. The printed circuit board memory module of claim 15, wherein each of the conductive traces is connected to a connector contact by a conductor-filled via.

18. The printed circuit board memory module of claim 17, wherein the conductor-filled via is a first conductor-filled via, and wherein each of the resistors bridges first and second embedded contact pads, the first contact pad being connected to the memory component by a second conductor-filled via, and the second contact pad being connected to one of the conductive traces.
